(19) United States
(12) Patent Application Publication
(10) Pub. No.: US 2025/0224456 A1
(43) Pub. Date: Jul. 10, 2025

(54) APPARATUS AND METHOD FOR CHECKING SoH OF TEST BATTERY IN USE

(71) Applicant: APRO Co., LTD, Anyang-si Gyeonggi-do (KR)

(72) Inventors: Jong Hyun LIM, Gunpo-si Gyeonggi-do (KR); Won Seok KO, Gunpo-si Gyeonggi-do (KR); Jeong Ha PARK, Gunpo-si Gyeonggi-do (KR)

(73) Assignee: APRO Co., LTD, Anyang-si Gyeonggi-do (KR)

(21) Appl. No.: 19/004,855

(22) Filed: Dec. 30, 2024

(30) Foreign Application Priority Data
Jan. 4, 2024 (KR) 10-2024-0001548

(51) Int. Cl. G01R 31/392; G01R 31/367; G01R 31/3835

(52) U.S. Cl. CPC G01R 31/392; G01R 31/367; G01R 31/3835

(57) ABSTRACT

There is provided a discharging unit configured to discharge a test battery as a test target in a preset environment, a data collection unit configured to select a preset number of points while the test battery is being discharged by the discharging unit and collect input data during the discharging process or within the selected points, a sensor unit configured to sense a voltage of the test battery, a preprocessing unit configured to preprocess the data collected by the data collection unit, a training unit configured to train an artificial intelligence learning model by performing training on a preset architecture using the data subjected to the preprocessing unit as an input value and a maximum battery available capacity as an output value, and a prediction unit configured to test an SoH of the test battery using the input value subjected to the preprocessing unit into the artificial intelligence learning model.

### CROSS-REFERENCE TO RELATED APPLICATION

The present application claims priority under 35 U.S.C. § 119(a) to Korean Patent Application No. 10-2024-0001548, filed in the Korean Intellectual Property Office on Jan. 4, 2024, the entire disclosure of which is incorporated herein by reference.

### BACKGROUND

### 1. Technical Field

The present embodiment relates to an apparatus and method for testing a state of health (SoH) of a test battery in use.

### 2. Related Art

Contents described in this section simply provide background information about the present embodiment and do not constitute the related art.

Batteries are used in any field such as electric vehicles, renewable energy systems, smart grids, portable electronic devices, and the like.

A state of health (SoH) of a battery is an indicator of the health and performance of the battery and includes information such a lifetime, storage capacity, or efficiency of the battery. It is very important to accurately identify the SoH of the battery in electric vehicles, portable electronic devices, or energy storage systems. Fast and accurate SoH evaluation enables efficient management and optimized use of batteries and improves the reliability and stability of the entire system.

Accordingly, along with the advancement of battery technology, the demand for more accurate and efficient SoH evaluation methods is increasing.

### SUMMARY

One embodiment of the present disclosure is directed to providing an apparatus and method for testing a state of health (SoH), which are capable of testing an SoH of a test battery in use and quickly accurately identifying the SoH of the test battery.

According to an aspect of the present embodiment, there is provided a discharging unit configured to discharge a test battery as a test target in a preset environment, a data collection unit configured to select a preset number of points while the test battery is being discharged by the discharging unit and collect input data during the discharging process or within the selected points, a sensor unit configured to sense a voltage of the test battery, a preprocessing unit configured to preprocess the data collected by the data collection unit, a training unit configured to train an artificial intelligence learning model by performing training on a preset architecture using the data subjected to the preprocessing unit as an input value and a maximum battery available capacity as an output value, and a prediction unit configured to test an SoH of the test battery using the input value subjected to the preprocessing unit into the artificial intelligence learning model trained by the training unit.

According to an aspect of the present embodiment, the preset number of points may be several tens.

According to an aspect of the present embodiment, the preset number of points may be within a preset error range based on 20 points.

According to an aspect of the present embodiment, the data collection unit may select a preset number of points at each time interval.

According to an aspect of the present embodiment, the data collection unit may select a preset number of points at a random time point.

According to an aspect of the present embodiment, the apparatus may further include a memory unit configured to store the artificial intelligence learning model trained by the training unit.

According to an aspect of the present embodiment, there is provided a method of testing a state of health (SoH) of a test battery by an apparatus for testing the SoH, which includes an idle operation of idling the test battery after charging the test battery in a preset manner, a discharging operation of discharging the test battery in a preset environment, a collecting operation of selecting a preset number of points during the discharging operation of the test battery and collecting input data during the discharging operation or within the selected points, a preprocessing operation of preprocessing the data collected during the collecting operation, a training operation of training an artificial intelligence learning model that uses the data preprocessed during the preprocessing operation as an input value and a maximum available battery capacity as an output value, and a predicting operation of inputting the data preprocessed during the preprocessing operation as input values of the trained artificial intelligence learning model and predicting the SoH of the test battery.

According to an aspect of the present embodiment, the preset number of points may be several tens.

According to an aspect of the present embodiment, the preset number of points may be within a preset error range based on 20 points.

According to an aspect of the present embodiment, the collecting operation may include selecting a preset number of points at each time interval.

According to an aspect of the present embodiment, the collecting operation may include selecting a preset number of points at a random time point.

According to an aspect of the present embodiment, the discharging operation may include discharging the test battery with a preset magnitude of a constant current for a preset time.

As described above, according to an aspect of the present embodiment, it is possible to test the SoH of the test battery in use and quickly accurately identify the SoH of the test battery.

### BRIEF DESCRIPTION OF THE DRAWINGS

FIG. 1 is a view illustrating a configuration of an apparatus for testing a state of health (SoH) according to one embodiment of the present disclosure.

FIG. 2 is a graph illustrating a change in voltage over time of a test battery discharged by a discharging unit according to one embodiment of the present disclosure.

FIG. 3 is a graph illustrating various changes in voltage over time of the test battery discharged by the discharging unit according to one embodiment of the present disclosure.

FIG. 4 is a flowchart illustrating a method of training an artificial intelligence learning model for testing the SoH of the test battery by the apparatus for testing an SoH according to one embodiment of the present disclosure.

FIG. 5 is a view illustrating a method of preprocessing data by the apparatus for testing an SoH according to one embodiment of the present disclosure.

FIG. 6 is a flowchart illustrating a method of testing an SoH using the artificial intelligence learning model by the apparatus for testing an SoH according to one embodiment of the present disclosure.

### DETAILED DESCRIPTION

Since the present disclosure may have various changes and various embodiments, specific embodiments are illustrated and described in the accompanying drawings. However, it should be understood that it is not intended to limit specific embodiments, and it should be understood to include all modifications, equivalents, and substitutes included in the spirit and scope of the present invention. Like reference numerals have been used for like components throughout the description of each drawing.

Terms such as first, second, A, B, and the like may be used to describe various components, but the components should not be limited by the terms. The terms are used only for the purpose of distinguishing one component from another. For example, a second component may be referred to as a first component, and similarly, the first component may also be referred to as the second component without departing from the scope of the present disclosure. The term “and/or” includes a combination of a plurality of related listed items or any of the plurality of related listed items.

When a first component is described as being “connected” or “coupled” to a second component, it should be understood that the first component may be directly connected or coupled to the second component or a third component may be present therebetween. On the other hand, when a certain component is described as being “directly connected” or “directly coupled” to another component, it should be understood that still another component is not present therebetween.

The terms used in the present application are only used to describe specific embodiments and are not intended to limit the present invention. The singular includes the plural unless the context clearly dictates otherwise. It should be understood that the term such as “comprise,” “have,” or the like in this application does not preclude the possibility of the presence or addition of features, numbers, steps, operations, components, parts, or a combination thereof in advance.

Unless otherwise, all terms used herein, including technical or scientific terms, have the same meaning as commonly understood by those skilled in the art to which the present disclosure pertains.

Terms such as those defined in a commonly used dictionary should be construed as having a meaning consistent with the meaning in the context of the related art and should not be construed in an ideal or excessively formal meaning unless explicitly defined in the application.

In addition, each component, procedure, process, method, or the like included in each embodiment of the present disclosure can be shared within the range in which there is no contradiction in terms of technology.

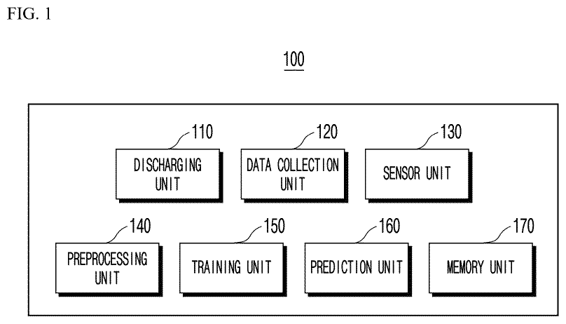

FIG. 1 is a view illustrating a configuration of an apparatus for testing a state of health (SoH) according to one embodiment of the present disclosure.

Referring to FIG. 1, an apparatus 100 for testing an SoH (hereinafter referred to as an “apparatus”) according to one embodiment of the present disclosure includes a discharging unit 110, a data collection unit 120, a sensor unit 130, a preprocessing unit 140, a training unit 150, a prediction unit 160, and a memory unit 170.

A battery is one battery cell or a plurality of battery cells electrically connected and modularized. A battery typically used in an electric vehicle, a renewable energy system, a smart grid, a portable electronic device, or the like includes a plurality of battery modules.

Here, an SoH of the battery refers to the current performance of the battery in comparison to the initial performance of the battery and is an indicator indicating a current remaining lifetime and current performance level of the battery. The apparatus 100 may accurately measure an SoH of a test battery. In particular, the apparatus 100 may measure the SoH relatively accurately while minimizing a test time for the test battery in use.

The discharging unit 110 discharges the test battery as a test target in a preset environment. Since the discharging unit 110 discharges each test battery without separate preprocessing, the test time can be minimized.

The data collection unit 120 collects input data during the process of discharging the test battery by the discharging unit 110. The data collection unit 120 collects input data during the process of discharging the test battery.

The data collection unit 120 may select a preset number of points during the process of discharging the test battery and collect (some) input data within the selected points. The data collection unit 120 may select a preset number of points at each time interval or at a random time point. Here, the preset number may be several tens, and more specifically, may be about 20. The data collection unit 120 selects only the preset number of points during the entire process of discharging the test battery. The test battery may be discharged throughout the entire discharging process (like a test battery in a normal state) depending on an SoH state. However, in the case of a test battery with an abnormality, a case in which discharging ends in the middle may be present. Selection of the excessive number of points may cause a blank of data. Accordingly, the data collection unit 120 selects only the preset number of points and selects (some) input data.

The sensor unit 130 senses a voltage of the test battery. The sensor unit 130 senses the voltage of the test battery so that the discharging unit 110 may perform appropriate charging and discharging and the data collection unit 120 may collect data.

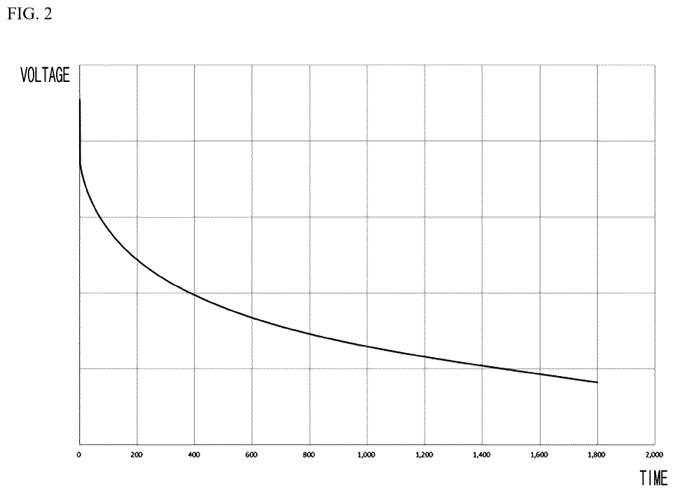

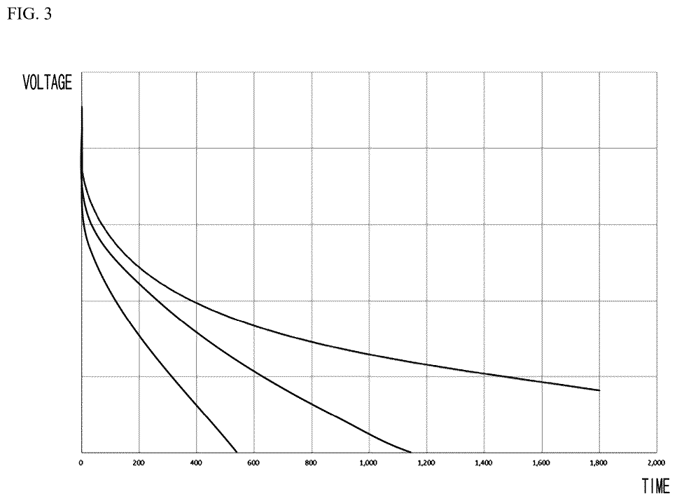

The operation of the discharging unit 110 and the collection process of the data collection unit 120 are illustrated in FIGS. 2 and 3.

FIG. 2 is a graph illustrating a change in voltage over time of a test battery discharged by a discharging unit according to one embodiment of the present disclosure, and FIG. 3 is a graph illustrating various changes in voltage over time of the test battery discharged by the discharging unit according to one embodiment of the present disclosure.

As illustrated in FIG. 2, the discharging unit 110 discharges the test battery with a preset magnitude of constant current for a preset time. Here, the (preset) magnitude of the constant current for discharging may be determined according to the capacity of the test battery and the preset time for discharging. For example, when discharging a test battery having a capacity of 100 mA/h per hour for 6 minutes, the discharging unit 110 may discharge the test battery with the preset magnitude of the constant current for the preset time. In this way, the discharging unit 110 discharges the test battery with the preset magnitude of the constant current for the preset time.

As illustrated in FIG. 3, a test battery without an abnormality is discharged for a predetermined time. On the other hand, a test battery with an abnormality cannot be discharged for the entire period in which the test battery without an abnormality is continuously discharged, and ends discharging in the middle.

Considering such a point, the data collection unit 120 may select the preset number of points in a situation in which the test battery is being discharged and collect input data within the selected points. After selecting the points, the data collection unit 120 collects the following input data. The data collection unit 120 collects a change rate of a voltage over time (slope, dv/dt) at each point, a differential capacity (dQ/dv) at each point, and a magnitude of a voltage in the test battery when discharging is finally performed.

Referring back to FIG. 1, the preprocessing unit 140 performs preprocessing on the data collected by the data collection unit 120.

The preprocessing unit 140 performs preprocessing for training or prediction on the input data collected by the data collection unit 120.

The preprocessing unit 140 performs scaling on the input data collected by the data collection unit 120. The preprocessing unit 140 distinguishes maximum and minimum values for each type of input data collected by the data collection unit 120 and performs scaling on the size of each data. Representatively, the preprocessing unit 140 may scale the size of data within the range of [0, 1].

The preprocessing unit 140 performs a zero point shift on each data after scaling and then performs normalization.

Furthermore, the preprocessing unit 140 may image the data subjected to the above-described process depending on the type of architecture for the training unit 150 to train input and output values. The preprocessing unit 140 may image the data using a technique such as a Gramian angular field (GAF), a Markov transition field (MTF), a recurrence plot (RP), or the like.

The training unit 150 trains an artificial intelligence learning model using the data subjected to the preprocessing unit 140 as input values and a maximum available battery capacity as an output value. The training unit 150 uses data collected by each type by the data collection unit 120 and preprocessed by the preprocessing unit 140 as input values and the maximum available battery capacity as an output value to perform training on a preset architecture. Here, the preset architecture may be a recurrent neural network (RNN) model or a long short-term memory (LSTM) model, or the like. The training unit 150 performs training on the corresponding architecture.

Furthermore, the training unit 150 may train an artificial intelligence learning model using data additionally imaged by the preprocessing unit 140 as input values and the maximum available battery capacity as an output value. In this case, the architecture used may be a model specialized in image processing such as a convolutional neural network (CNN). Relatively, architectures that receive images as input values exhibit excellent characteristics in terms of training efficiency or inference accuracy. Accordingly, the training unit 150 may perform training on an architecture specialized in image processing using an imaged image as an input value.

The prediction unit 160 inputs the input value subjected to the preprocessing unit 140 into the learning model (trained by the training unit 150) to test the SoH of the test battery. As described above, the SoH refers to a current performance ratio of the test battery to the initial performance of the battery. The initial performance of the test battery corresponds to known information as information provided by manufacturers. The current performance of the test battery corresponds to the output value of the artificial intelligence learning model. The prediction unit 160 inputs the input value subjected to the preprocessing unit 140 into the learning model (trained by the training unit 150) to infer the current performance of the test battery. Thereafter, the prediction unit 160 calculates the current performance ratio of the test battery to the initial performance of the battery and tests the SoH of the test battery.

The memory unit 170 stores the data trained by the training unit 150 and the artificial intelligence learning model. The memory unit 170 stores the corresponding data so that the prediction unit 160 may predict the SoH of the test battery using the artificial intelligence learning model.

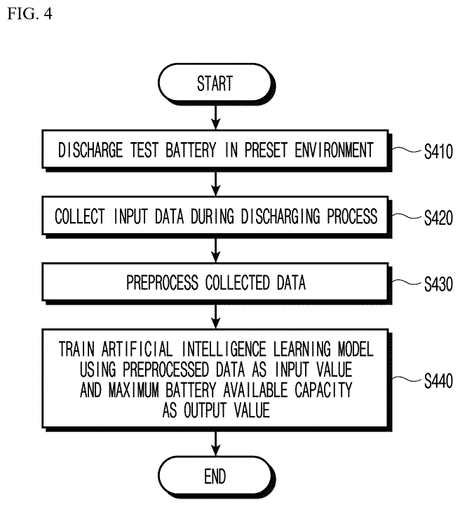

FIG. 4 is a flowchart illustrating a method of training an artificial intelligence learning model for testing the SoH of the test battery by the apparatus for testing an SoH according to one embodiment of the present disclosure.

The discharging unit 110 discharges the test battery in a preset environment (S410).

The data collection unit 120 collects input data during the discharging process of the test battery (S420).

The preprocessing unit 140 preprocesses the data collected by the data collection unit 120 (S430).

The training unit 150 trains the artificial intelligence learning model that uses the preprocessed data as an input value and the maximum available battery capacity as an output value (S440).

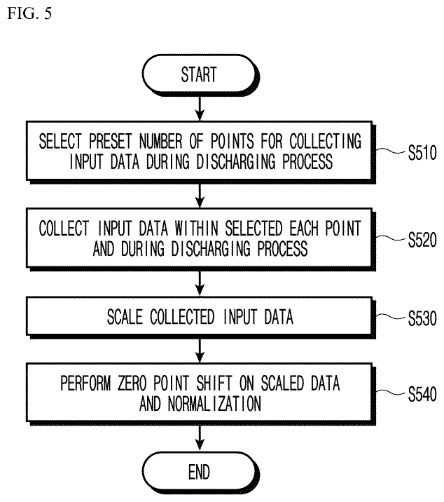

FIG. 5 is a view illustrating a method of preprocessing data by the apparatus for testing an SoH according to one embodiment of the present disclosure.

The preprocessing unit 140 selects a preset number of points for collecting input data during the discharging process (S510).

The preprocessing unit 140 collects input data from each selected point and during the discharging process (S520).

The preprocessing unit 140 scales the collected input data (S530).

The preprocessing unit 140 performs zero point shift and normalization on the scaled data (S540).

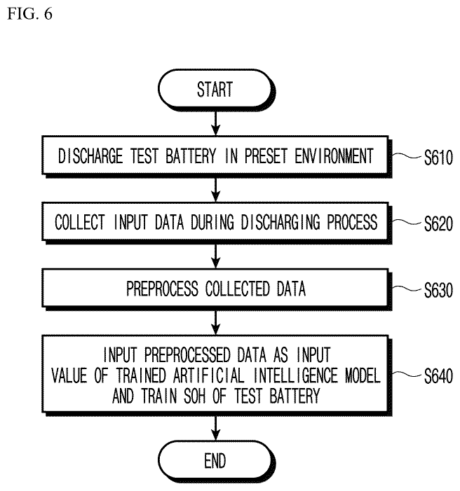

FIG. 6 is a flowchart illustrating a method of testing an SoH using the artificial intelligence learning model by the apparatus for testing an SoH according to one embodiment of the present disclosure.

The discharging unit 110 discharges the test battery in a preset environment (S610).

The data collection unit 120 collects input data during the discharging process of the test battery (S620).

The preprocessing unit 140 preprocesses the data collected by the data collection unit 120 (S630).

The prediction unit 160 inputs the preprocessed data as input values of the trained artificial intelligence learning model and predicts the SoH of the test battery (S640).

Although each process is described as being executed sequentially in FIGS. 4 to 6, this is merely an example of the technical idea of one embodiment of the present disclosure. That is, since those skilled in the art to which one embodiment of the present disclosure pertains can modify and change the present embodiment in various ways and apply the modifications and changes by changing the order described in each drawing to perform the processes or executing one or more of processes in parallel without departing from the essential characteristics of one embodiment of the present disclosure, FIGS. 4 to 6 are not limited to the time-series order.

Meanwhile, the processes illustrated in FIGS. 4 to 6 may be implemented as computer-readable codes on a computer-readable recording medium. The computer-readable recording medium includes any type of recording device in which data that may be read by a computer system are stored. That is, the computer-readable recording medium may include a storage medium such as a magnetic storage medium (e.g., a read only memory (ROM), a floppy disk, a hard disk, or the like) and an optical reading medium (e.g., a CD-ROM, a DVD, or the like). In addition, the computer-readable recording medium may be distributed to a computer system connected via a network so that computer-readable code may be stored and executed in a distributed manner.

The above description is merely the exemplary description of the technical spirit of the present embodiment, and those skilled in the art to which the present embodiment pertains will be able to modify and change the present embodiment in various ways without departing from the essential characteristics of the present embodiment. Accordingly, the present embodiments are not intended to limit the technical spirit of the present embodiment, but are intended to describe the same, and the scope of the technical spirit of the present embodiment is not limited by these embodiments. The scope of the present embodiment should be construed by the appended claims, and all technical ideas within the equivalent scope should be construed as being included in the scope of the present embodiment.

What is claimed is:

1. An apparatus for testing a state of health (SoH), comprising:
a discharging unit configured to discharge a test battery as a test target in a preset environment;
a data collection unit configured to select a preset number of points while the test battery is being discharged by the discharging unit and collect input data during the discharging process or within the selected points;
a sensor unit configured to sense a voltage of the test battery;
a preprocessing unit configured to preprocess the data collected by the data collection unit;
a training unit configured to train an artificial intelligence learning model by performing training on a preset architecture using the data subjected to the preprocessing unit as an input value and a maximum battery available capacity as an output value; and
a prediction unit configured to test an SoH of the test battery using the input value subjected to the preprocessing unit into the artificial intelligence learning model trained by the training unit.

2. The apparatus of claim 1, wherein the preset number of points is several tens.

3. The apparatus of claim 2, wherein the preset number of points is within a preset error range based on 20 points.

4. The apparatus of claim 1, wherein the data collection unit selects a preset number of points at each time interval.

5. The apparatus of claim 1, wherein the data collection unit selects a preset number of points at a random time point.

6. The apparatus of claim 1, further comprising a memory unit configured to store the artificial intelligence learning model trained by the training unit.

7. A method of testing a state of health (SoH) of a test battery by an apparatus for testing the SoH, the method comprising:
an idle operation of idling the test battery after charging the test battery in a preset manner;
a discharging operation of discharging the test battery in a preset environment;
a collecting operation of selecting a preset number of points during the discharging operation of the test battery and collecting input data during the discharging operation or within the selected points;
a preprocessing operation of preprocessing the data collected during the collecting operation;
a training operation of training an artificial intelligence learning model that uses the data preprocessed during the preprocessing operation as an input value and a maximum available battery capacity as an output value; and
a predicting operation of inputting the data preprocessed during the preprocessing operation as input values of the trained artificial intelligence learning model and predicting the SoH of the test battery.

8. The method of claim 7, wherein the preset number of points is several tens.

9. The method of claim 8, wherein the preset number of points is within a preset error range based on 20 points.

10. The method of claim 7, wherein the collecting operation includes selecting a preset number of points at each time interval.

11. The method of claim 7, wherein the collecting operation includes selecting a preset number of points at a random time point.

12. The method of claim 7, wherein the discharging operation includes discharging the test battery with a preset magnitude of a constant current for a preset time.
